(19) United States
(12) Patent Application Publication
(10) Pub. No.: US 2026/0139200 A1
(43) Pub. Date: May 21, 2026

(54) COMPOSITIONS AND METHODS FOR VAPOR PHASE SURFACE MODIFICATION

(71) Applicant: Fujifilm Electronic Materials U.S.A., Inc., N. Kingstown, RI (US)

(72) Inventor: William A. Wojtczak, Mesa, AZ (US)

(21) Appl. No.: 19/389,144

(22) Filed: Nov. 14, 2025

Related U.S. Application Data
(60) Provisional application No. 63/720,797, filed on Nov. 15, 2024.

(51) Int. Cl. C11D 3/16; C11D 3/20; C11D 3/43; H01L 21/02

(52) U.S. Cl. CPC C11D 3/162; C11D 3/20; C11D 3/43; H10P 70/23; H10P 70/27

(57) ABSTRACT

This disclosure provides surface treatment compositions and methods for use thereof. In some embodiments, the compositions are dispersed onto the surface of a substrate in a vapor phase. In some embodiments, the compositions are dispersed onto the surface of the substrate in a liquid phase.

### CROSS REFERENCE TO RELATED APPLICATION

The present application claims priority to U.S. Provisional Application Ser. No. 63/720,797, filed on Nov. 15, 2024, the contents of which are hereby incorporated by reference in their entirety.

### TECHNICAL FIELD

This disclosure relates generally to surface treatment, and more particularly to vapor treatment of semiconductor surfaces where formation of a hydrophobic layer is desired.

### BACKGROUND

At sub-20 nm critical dimensions, pattern collapse of FinFET's and dielectric stacks during wet clean and drying has become a major problem in semiconductor manufacturing processes. The conventional theory of pattern collapse implicates high capillary forces during rinse and dry as major contributors leading to the collapse phenomenon. However, other chemical and substrate properties may play an important role as well, namely, liquid surface tension and viscosity, substrate mechanical strength, pattern density and aspect ratio, and cleaner chemistry damage to substrate surfaces.

### SUMMARY

It has been found that low surface tension modifying compositions that impart the surfaces of a semiconductor substrate (e.g., a silicon or copper wafer) with a hydrophobic layer (e.g., a hydrophobic monolayer) can minimize the capillary forces that drive pattern collapse during a drying process. Without wishing to be bound by theory, it is believed that the Laplace pressure is minimized when the contact angle, i.e., the angle a liquid (e.g., water) creates when in contact with a substrate surface, is at or near 80 degrees. This in combination with the presence of a low surface tension fluid can greatly reduce the forces that cause pattern collapse.

This disclosure provides surface treatment compositions and methods for use thereof. In some embodiments, the compositions are dispersed onto the surface of a substrate in a vapor phase. In some embodiments, the compositions are dispersed onto the surface of the substrate in a liquid phase.

In some embodiments of the disclosure, there are provided surface treatment compositions comprising at least one silylating agent, at least one ketone, at least one organic anhydride; and at least one solvent.

In some embodiments, there are provided surface treatment compositions comprising at least one silylating agent, at least one ketone; and at least one solvent. In some embodiments, the compositions further comprise at least one organic anhydride.

In some embodiments, there are provided surface treatment compositions comprising at least one silylating agent, at least one organic anhydride; and at least one solvent. In some embodiments, the compositions further comprise at least one ketone.

In some embodiments, the silylating agent is a disilazane. In certain embodiments, the disilazane is 1,1,3,3-tetramethyldisilazane, hexamethyldisilazane, heptamethyldisilazane, N-methyl hexamethyldisilazane, 1,3-diphenyltetramethyldisilazane, or 1,1,3,3-tetraphenyl-1,3-dimethyldisilazane.

In some embodiments, the silylating agent includes a trimethylsilyl group. Silylating agents bearing a trimethylsilyl group include N-(trimethylsilyl)dimethylamine, N-(trimethylsilyl) diethylamine, 4-trimethylsilyloxy-3-penten-2-one, bis-trimethylsilylsulfate, methoxytrimethylsilane, N-allyl-N,N-bis(trimethylsilyl)amine, N,N-bis-trimethylsilyl urea, or tris-trimethylsilylphosphite.

In some embodiments, the silylating agent is an aminosilane. In certain embodiments, the aminosilane is bis(dimethylamino)dimethylsilane or phenethyldimethyl(dimethylamino) silane.

In some embodiments, the silylating agent comprises from about 5 wt % to about 20 wt % of the composition.

In some embodiments of the invention, the ketone is a monoketone or a diketone. In some embodiments, the ketone is a C₁-C₁₀ ketone. In some embodiments, the ketone is a diketone. In some embodiments, the ketone is acetylacetone. In some embodiments, the ketone is a monoketone. In some embodiments, the ketone is acetone, methyl ethyl ketone, methyl propyl ketone, methyl butyl ketone, methyl pentyl ketone, methyl hexyl ketone, methyl heptyl ketone, methyl octyl ketone, methyl amyl ketone, cyclohexanone, or cyclopentanone. In some embodiments, the ketone comprises from about 2 wt % to about 15 wt % of the composition.

In some embodiments, the organic anhydride is selected from formic anhydride, acetic anhydride, propionic anhydride, or butyric anhydride. In certain embodiments, the organic anhydride comprises from about 2 wt % to about 20 wt % of the composition.

In some embodiments, the at least one solvent is selected from the group consisting of carbonate solvents, lactones, ketones, aromatic hydrocarbons, siloxanes, alkyl ethers, glycol dialkyl ethers, glycol alkyl ether acetates, esters, ureas, lactams, dimethyl sulfoxide, and N-methyl pyrrolidone. In some embodiments, the solvent is selected from glycol dialkyl ethers or glycol alkyl ether acetates. In certain embodiments, the solvent comprises from about 70 wt % to about 95 wt % of the composition.

In some embodiments of the disclosure, there are provided methods for treating a semiconductor substrate having a pattern disposed on a surface of the substrate. Such methods can be performed, for example, by:
contacting the surface of the substrate with a surface treatment composition, wherein the composition is dispersed onto the surface of the substrate in the vapor phase, wherein the composition comprises at least one silylating agent, at least one solvent, and at least one catalyst,
wherein the surface treatment composition forms a surface treatment layer on the surface such that the surface has a water contact angle of at least about 50 degrees; and
wherein the pattern comprises a feature having a dimension of at most about 20 nm.

In some embodiments of the disclosure, there are provided methods for treating a semiconductor substrate having a pattern disposed on a surface of the substrate. Such methods can be performed, for example, by:
contacting the surface of the substrate with a surface treatment composition, wherein the
composition is dispersed onto the surface of the substrate in the vapor phase, wherein the composition comprises at least one silylating agent; at least one ketone; at least one organic anhydride; and at least one solvent.

In some embodiments of the disclosure, there are provided methods for treating a semiconductor substrate having a pattern disposed on a surface of the substrate. Such methods can be performed, for example, by: contacting the surface of the substrate with a surface treatment composition, wherein the composition is dispersed onto the surface of the substrate in the vapor phase, wherein the composition comprises at least one silylating agent, at least one solvent, and at least one catalyst, and wherein the composition forms a hydrophobic film on the surface of the substrate.

In some embodiments of the disclosure, there are provided methods for treating a semiconductor substrate having a pattern disposed on a surface of the substrate. Such methods can be performed, for example, by: contacting the surface of the substrate with a surface treatment composition, wherein the composition is dispersed onto the surface of the substrate in the vapor phase, wherein the composition comprises at least one silylating agent and at least one solvent; wherein the surface treatment composition forms a surface treatment layer on the surface such that the surface has a water contact angle of at least about 50 degrees; and wherein the pattern comprises a feature having a dimension of at most about 20 nm. In certain aspects of this embodiment, the composition further comprises a catalyst.

In some embodiments of the disclosure, there are provided articles comprising: a semiconductor substrate; and the surface treatment composition of this disclosure supported by the semiconductor substrate.

### DETAILED DESCRIPTION OF THE DISCLOSURE

In some embodiments, this disclosure relates to surface treatment methods. Such methods can be performed, for example, by contacting the surface of the substrate with a surface treatment composition, wherein the composition is dispersed onto the surface of the substrate in the vapor phase, wherein the composition comprises at least one silylating agent, at least one solvent, and at least one catalyst, wherein the surface treatment composition forms a surface treatment layer on the surface such that the surface has a water contact angle of at least about 50 degrees; and wherein the pattern comprises a feature having a dimension of at most about 20 nm.

Semiconductor substrates that can be treated by the surface treatment compositions described herein typically are constructed of silicon, silicon germanium, silicon nitride, copper, Group III-V compounds such as GaAs, or any combination thereof. In some embodiments, the semiconductor substrate can be a silicon wafer, a copper wafer, a silicon dioxide wafer, a silicon nitride wafer, a silicon oxynitride wafer, a carbon doped silicon oxide wafer, a SiGe wafer, or a GaAs wafer. The semiconductor substrates may additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, nickel, silicon, polysilicon titanium nitride, tantalum nitride, tin, tungsten, SnAg, SnAg/Ni, CuNiSn, CuCoCu, and CoSn. The semiconductor substrate may also contain layers of interlayer dielectrics, silicon oxide, silicon nitride, titanium nitride, silicon carbide, silicon oxide carbide, silicon oxide nitride, titanium oxide, and carbon doped silicon oxides.

In some embodiments, the semiconductor substrate surface to be treated by the surface treatment compositions described herein includes features containing SiO₂, SiN, TIN, SiOC, SiON, Si, SiGe, Ge, or W. In some embodiments, the substrate semiconductor surface includes features containing SiO₂ and/or SiN.

In general, the semiconductor substrate surface to be treated by the surface treatment compositions described herein includes patterns formed by a prior semiconductor manufacturing process (e.g., a lithographic process including applying a photoresist layer, exposing the photoresist layer to an actinic radiation, developing the photoresist layer, etching the semiconductor substrate beneath the photoresist layer, and/or removing the photoresist layer). In some embodiments, the patterns can include features having at least one (e.g., two or three) dimension (e.g., a length, a width, and/or a depth) of at most about 20 nm (e.g., at most about 15 nm, at most about 10 nm, or at most about 5 nm) and/or at least about 1 nm (e.g., at least about 2 nm or at least about 5 nm).

In general, the surface treatment compositions described herein include at least one (e.g., two, three, or four) solvent and at least one (e.g., two, three, or four) silylating agent. In some embodiments, the solvent is selected from the group consisting of carbonate solvents (e.g., propylene carbonate or dimethyl carbonate), lactones (e.g., gamma-butyrolactone), ketones (e.g., cyclohexanone), aromatic hydrocarbons (e.g., toluene, xylene, or mesitylene), siloxanes (e.g., hexamethyldisiloxane), alkyl ethers, glycol dialkyl ethers (e.g., dipropylene glycol dimethyl ether or propylene glycol dimethyl ether), glycol alkyl ether acetates (e.g., propylene glycol methyl ether acetate (PGMEA)), esters (e.g., ethyl lactate), ureas (e.g., 1,3-dimethyl-2-imidizolidinone or 1,3-dimethyl-3,4,5,6-tetrahydro-2 (1H)-pyrimidinone), lactams, dimethyl sulfoxide, and N-methyl pyrrolidone.

In some embodiments, the solvent is selected from the group consisting of glycol alkyl ether acetates. In some embodiments, the solvent is propylene glycol methyl ether acetate (PGMEA).

In some embodiments, the at least one solvent is from at least about 70 wt percent (e.g., at least about 72 wt percent, at least about 74 wt percent, at least about 76 wt percent, at least about 78 wt percent, at least about 80 wt percent, at least about 82 wt percent, at least about 84 wt percent, or at least about 88 wt percent) to at most about 95 wt percent (e.g., at most about 94 wt percent, at most about 93 wt percent, at most about 92 wt percent, or at most about 91 wt percent) of the surface treatment compositions described herein.

In general, the compositions of the disclosure contain at least one silylating agent. In some embodiments, the silylating agents can be disilazanes. For example, the silylating agent can be hexamethyldisilazane, heptamethyldisilazane, N-methyl hexamethyldisilazane, 1,3-diphenyltetramethyldisilazane, or 1,1,3,3-tetraphenyl-1,3-dimethyldisilazane.

In some embodiments, the silylating agents contemplated for use in the compositions and methods of the disclosure are selected from the group consisting of compounds including a trimethylsilyl group. For example, the silylating agent can be N-(trimethylsilyl)dimethylamine, N-(trimethylsilyl) diethylamine, 4-trimethylsilyloxy-3-penten-2-one, bis(trimethylsilyl) sulfate, methoxytrimethylsilane, N-allyl-N,N-bis(trimethylsilyl)amine, N-(trimethylsilyl) diethylamine, N,N-bis(trimethylsilyl) urea, or tris(trimethylsilyl)phosphite.

In some embodiments, the silylating agents contemplated for use in the compositions and methods of the disclosure are selected from the group consisting of aminosilanes. For example, the aminosilane can be bis(dimethylamino)dimethylsilane or phenethyldimethyl(dimethylamino) silane.

In some embodiments, the at least one silylating agent is from at least about 5.0 wt percent (e.g., at least about 7 wt percent, at least about 9 wt percent, at least about 10 wt percent, at least about 12 wt percent, at least about 13 wt percent) to at most about 20 wt percent (e.g., at most about 19 wt percent, at most about 18 wt percent, or at most about 17 wt percent) of the surface treatment compositions described herein.

Without wishing to be bound by theory, it is believed that the surface treatment compositions described herein can form a surface treatment layer (e.g., a hydrophobic layer such as a hydrophobic monolayer) on a patterned surface of a semiconductor substrate such that the patterned surface has a water contact angle of at least about 50 degrees (e.g., at least about 55 degrees, at least about 60 degrees, at least about 65 degrees, at least about 70 degrees, at least about 75 degrees, at least about 80 degrees, at least about 85 degrees, at least about 89 degrees, at least about 90 degrees, at least about 95 degrees, or at least about 100 degrees). Without wishing to be bound by theory, it is believed that such a surface treatment layer can prevent or minimize the collapse of the patterned features on the semiconductor substrate during a cleaning or drying step typically used in the semiconductor manufacturing process. In some embodiments, upon treatment with the surface treatment compositions described herein, at least about 70 percent (e.g., at least about 75 percent, at least about 80 percent, at least about 85 percent, at least about 90 percent, at least about 95 percent, at least about 98 percent, or at least about 99 percent) of the features (e.g., pillars or sheets) on a patterned wafer can remain uncollapsed after a cleaning or drying step. The pattern features can be oriented vertically or horizontally relative to the substrate.

In some embodiments, the surface treatment compositions described herein can further include at least one catalyst. Exemplary catalysts include, but are not limited to, ketones, anhydrides (e.g., phthalic anhydride or acetic anhydride), organic acids (e.g., sulfonic acids such as methanesulfonic acid or trifluoromethane-sulfonic acid), inorganic acids (e.g., sulfuric acid).

In some embodiments of the invention, the ketone is a monoketone or a diketone. In some embodiments, the ketone is a C₁-C₁₀ ketone. In some embodiments, the ketone is a diketone. In some embodiments, the ketone is acetylacetone. In some embodiments, the ketone is a monoketone. In some embodiments, the ketone is acetone, methyl ethyl ketone, methyl propyl ketone, methyl butyl ketone, methyl pentyl ketone, methyl hexyl ketone, methyl heptyl ketone, methyl octyl ketone, methyl amyl ketone, cyclohexanone, or cyclopentanone. In some embodiments, the ketone comprises from about 2 wt % to about 15 wt % of the composition.

In some embodiments, the organic anhydride is selected from formic anhydride, acetic anhydride, propionic anhydride, or butyric anhydride. In certain embodiments, the organic anhydride comprises from about 2 wt % to about 20 wt % of the composition.

Without wishing to be bound by theory, it is believed that the catalyst can facilitate the formation of the surface treatment layer by the surface treatment agent on a patterned surface of a semiconductor substrate (e.g., through facilitating a reaction between the surface treatment agent and the patterned surface).

In some embodiments, each component of the compositions of the disclosure independently has a vapor pressure at ambient temperature of greater than 1 Torr. In some embodiments, the vapor pressure of each component independently is greater than 2 Torr. In some embodiments, the vapor pressure of each component independently is greater than 5 Torr. In some embodiments, the vapor pressure of each component independently is greater than 10 Torr. As used herein, ambient temperature is a temperature between about 22° C. and about 25° C.

In some embodiments, the surface treatment compositions described herein can specifically exclude one or more of the additive components, in any combination, if more than one. Such components are selected from the group consisting of non-aromatic hydrocarbons, cyclic silazanes (e.g., heterocyclic silazanes), protic solvents (e.g., alcohols or amides), lactones (e.g., those with 5- or 6-membered rings), certain Si-containing compounds (e.g., those having a Si—H group or an aminosilyl group), polymers, oxygen scavengers, quaternary ammonium salts including quaternary ammonium hydroxides, amines, bases (such as alkaline bases (e.g., NaOH, KOH, LiOH, Mg(OH)₂, and Ca(OH)₂)), surfactants, defoamers, fluoride-containing compounds (e.g., HF, H₂SiF₆, H₂PF₆, HBF₄, NH₄F, and tetraalkylammonium fluoride), oxidizing agents (e.g., peroxides, hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, ammonium persulfate, tetramethylammonium chlorite, tetramethylammonium chlorate, tetramethylammonium iodate, tetramethylammonium perborate, tetramethylammonium perchlorate, tetramethylammonium periodate, tetramethylammonium persulfate, urea hydrogen peroxide, and peracetic acid), abrasives, silicates, hydroxycarboxylic acids, carboxylic and polycarboxylic acids lacking amino groups, silanes (e.g., alkoxysilanes), cyclic compounds (e.g., cyclic compounds containing at least two rings, such as substituted or unsubstituted naphthalenes, or substituted or unsubstituted biphenylethers) other than the cyclosiloxanes described herein, chelating agents (e.g., azoles, diazoles, triazoles, or tetrazoles), corrosion inhibitors (such as azole or non-azole corrosion inhibitors), buffering agents, guanidine, guanidine salts, pyrrolidone, polyvinyl pyrrolidone, metal halides, and metal-containing catalysts.

In some embodiments, the surface treatment methods described herein can further include contacting the surface of a substrate with at least one aqueous cleaning solution before contacting the surface with a surface treatment composition. In such embodiments, the at least one aqueous cleaning solution can include water, an alcohol, aqueous ammonium hydroxide, aqueous hydrochloric acid, aqueous hydrogen peroxide, an organic solvent, or a combination thereof.

In some embodiments, the surface treatment methods described herein can further include contacting the surface of a substrate with a first rinsing solution (e.g., water, an organic solvent such as isopropanol, or a combination thereof) after contacting the surface with the at least one aqueous cleaning solution but before contacting the surface with the surface treatment composition. In some embodiments, the surface treatment methods described herein can further include contacting the surface with a second rinsing solution (e.g., water, an organic solvent such as isopropanol, or a combination thereof) after contacting the surface with the surface treatment composition. In some embodiments, the surface treatment methods described herein can further include drying the surface (e.g., after contacting the surface with first rinsing solution, the surface treatment composition, or the second rinsing solution). In some embodiments, the surface treatment methods described herein can further include removing the surface treatment layer from the surface.

The semiconductor substrates contemplated for use can be further processed to form one or more circuits on the substrate or can be processed to form into a semiconductor device (e.g., an integrated circuit device such as a semiconductor chip) by, for example, assembling (e.g., dicing and bonding) and packaging (e.g., chip sealing).

In some embodiments, this disclosure features articles (e.g., an intermediate semiconductor article found during the manufacturing of a semiconductor device) that includes a semiconductor substrate, and a surface treatment composition described herein supported by the semiconductor substrate. The surface treatment composition can include at least one aprotic solvent and at least one Si-containing compound, such as those described above.

The present disclosure is illustrated in more detail with reference to the following examples, which are for illustrative purposes and should not be construed as limiting the scope of the present disclosure.

### EXAMPLES

### General Procedure

A patterned substrate pre-etched in hot H₃PO₄ acid, and thermal oxide monitor coupon were etched and cleaned using RCA clean sequence (DHF/SC-1) (Dilute HydroFluoric Acid (DHF), Standard Clean-1 (SC-1)); RCA Clean is also known as H₂O₂+NH₄OH+H₂O in various ratios). The thermal oxide monitor wafer was used to monitor the oxide etch rate and to measure the contact angle on the SiO₂ surface after the vapor surface modification technology (SMT) process. The purpose of the DHF step is two-fold, to increase the SiO₂ nanosheet aspect ratio of the incoming pattern from 9:1 to 26:1 and to clean the surface. In cases where a high aspect ratio was already achieved, by a preceding dry etch process, a much shorter or no DHF step may be needed. In general, a much greater tendency for collapse was observed during the drying of high aspect ratio features because of capillary and stiction forces. After DHF/SC-1, the wafers were rinsed with water and isopropanol or other rinses or combination of rinses in separate PTFE beakers prior to the vapor SMT step. The substrates were always maintained with liquid on the surface prior to the vapor SMT step to prevent stiction drying. At the vapor SMT step, all processing was moved into a glovebox with N₂ atmosphere to prevent reaction between surface modifying chemical and water vapor in room air. During the vapor SMT step the coupons were suspended horizontally and facedown 2-3 cm above the surface of the SMT liquid that is being vaporized. After vapor SMT, the wafer coupons were final rinsed in anhydrous IPA liquid (or vapor) and then dried with N₂ gas.

### Example 1

A 50 g vapor solution of 90% dimethyl carbonate (DMC) and 10% 1,1,3,3-tetramethyldisilazane (TMDS) by weight was heated to 88° C. and stirred at 300 rpm in a 300 mL PTFE beaker to achieve vaporization; post IPA rinsed coupons were bathed in the vapors to displace and remove the rinse or cleaning liquids. The vapors containing solvent and silylating agent also penetrate the pattern features of the substrate and modify the surface silanol groups to form a silylated Si—O—SiR₃ hydrophobic surface (R═H, alkyl, aryl, allyl, etc.). The vapor application of the surface modification chemistry minimizes the collapse inducing capillary forces on the pattern features. Post vapor SMT, the coupons were rinsed with IPA vapor or liquid and dried with pressurized N₂ gas. The process as described achieved a reduction in pattern collapse compared to other drying processes.

In this example, the chemical conditions for the wafer coupon process were: 200:1 DHF 21C@300 sec/DIW 21C@60 sec/1:2:100 SC-1 21C@90 sec./DIW 21C@60 sec/2×IPA 21C@120 sec./90% DMC+10% TMDS 88C @180 sec Vapor/2×IPA 21C@120 sec./N₂ gas dry 21C@45 psi @ 1 min.

The thermal oxide monitor coupon thickness was pre-measured prior to processing and then post measured after processing by standard ellipsometric methods. The difference in thickness divided by the DHF process time provided an etch rate of the SiO₂ surface for the DHF step. Contact angles for the thermal oxide monitor coupons were measured by the water drop method as follows:

The coupons were placed on the AST VCA 3000 Contact Angle Tool and the following procedure was followed to measure the contact angles:
1. Place the SiO₂ coupon onto the stage.
2. Raise the stage upward by rotating Vertical Knob clockwise until the specimen is just below the needle.
3 Dispense a drop of De-ionized water, lightly touching the specimen surface, then lower the specimen until the droplet separates from the needle tip.
4. Center the drop across the field-of-view using transverse knob for stage adjustment.
5. Focus the drop in field-of-view to get a sharp image by moving the stage along guide rails.
6. Click the “AutoFAST” button to freeze the image and calculate. Two numbers will be displayed; these are the left and right contact angles.
7. To calculate manually, use the mouse to place five markers around the droplet.
8 Select the droplet icon from the Main Menu to calculate the contact angle.
9. This will create a curve fit and tangent lines on the image. Two numbers will be displayed in the left-hand-corner of the screen; these are the left and right contact angles.
10. Repeat above procedure at 3 substrate sites and average the resulting contact angles and report the average result.

In general, a DIW drop contact angle of >85 degrees indicates a high degree of surface modification of the SiO₂ surface by the vaporized chemistry.

The vapor processed patterned substrates; containing ˜26:1 aspect ratio horizontal SiO₂ nanosheets with average width of 9-10 nm and average length of 255-270 nm were examined by scanning electron microscopy (SEM). Randomly selected 22 nanosheet containing features were measured at a magnification of 50000× and the number of un-collapsed nanosheets were tabulated from 3 such features to calculate an average uncollapsed %. The uncollapsed % is calculated by dividing the un-collapsed nanosheet number by the total starting nanosheet count for 3 feature sets and multiplying by 100. The length and width of 9 nanosheets of 3 features were measured at 1000000× and the dimensions were used to calculate the average aspect ratio for the features. In this way, the effectiveness of the vapor SMT chemistry and process in preventing pattern collapse was assessed.

### Example 2

A 50 g vapor SMT solution of 80% propylene glycol monomethyl ether acetate (PGMEA), 10% 1,1,3,3-tetramethyldisilazane (TMDS), and 10% acetylacetone (ACAC) by weight was heated to 105° C. and stirred at 300 rpm in a 300 mL PTFE beaker to achieve vaporization; post IPA rinsed coupons were bathed in the vapors to displace and remove the rinse or cleaning liquids. The vapors containing solvent and surface modifying agent also penetrate the pattern features of the substrate and modify the surface silanol groups to form a silylated Si—O—SiR₃ hydrophobic surface (R═H, alkyl, aryl, allyl, etc.). The vapor application of the surface modification chemistry minimizes the collapse inducing capillary forces on the pattern features. Post vapor SMT, the coupons were rinsed with IPA vapor or liquid and dried with pressurized N₂ gas. The process as described achieved a reduction in pattern collapse compared to other drying processes.

In this example, the chemical conditions for the wafer coupon process were: 200:1 DHF 21C@285 sec/DIW 21C@60 sec/1:2:100 SC-1 21C@90 sec./DIW 21C@60 sec/2×IPA 21C@120 sec./80% PGMEA+10% TMDS+10% ACAC 105C @180 sec Vapor/2×IPA 21C@120 sec./N₂ gas dry 45 psi.

The thermal oxide monitor coupon thickness and contact angle was measured in the same manner as described in Example 1. The vapor processed patterned substrates were analyzed by SEM as described in Example 1.

### Example 3

A 50 g vapor SMT solution of 90% acetylacetone (ACAC) and 10% 1,1,3,3-tetramethyldisilazane (TMDS) by weight was heated to 100 C and stirred at 300 rpm in a 300 mL PTFE beaker to achieve vaporization; post IPA rinsed coupons are bathed in the vapors to displace and remove the rinse or cleaning liquids. The vapors containing solvent and surface modifying agent also penetrate the pattern features of the substrate and modify the surface silanol groups to form a silylated Si—O—SiR₃ hydrophobic surface (R═H, alkyl, aryl, allyl, etc.). The vapor application of the surface modification chemistry minimizes the collapse inducing capillary forces on the pattern features. Post vapor SMT, the coupons were rinsed with IPA vapor or liquid and dried with pressurized N₂ gas. The process as described achieved a reduction in pattern collapse compared to other drying processes.

In this example, the chemical conditions for the wafer coupon process were: 200:1 DHF 21C@285 sec/DIW 21C@60 sec/1:2:100 SC-1 21C@90 sec./DIW 21C@60 sec/2×IPA 21C@120 sec./90% ACAC+10% TMDS 100C @180 sec Vapor/2×IPA 21C@120 sec./N₂ gas dry 45 psi.

The thermal oxide monitor coupon thickness and contact angle was measured in the same manner as described in Example 1.

The vapor processed patterned substrates were analyzed by SEM as described in Example 1.

### Example 4

For less demanding aspect ratio or pattern geometries, surface modification compositions described herein were applied as liquids instead of vapors to the substrate surface. In such applications the compositions described in Examples 1-3 were employed in the same manner as described except that during the SMT step the substrates were contacted with compositions of the disclosure in liquid phase, rather than vapor phase at temperatures between 21° C.-150° C. All other steps were substantially the same as in Examples 1-3.

Results from formulation examples FE-1 to FE-8 and comparative examples CE-1 and CE-2 used in the above Examples are depicted in Table 1 below.

TABLE 1

| | | | | | DHF | ThOx Etch | | | | SMT | SMT | un- |
|---|---|---|---|---|---|---|---|---|---|---|---|---|
| Formulation | | | Catalyst | Catalyst | Time | Rate in | CA | | SMT | Temp. | Time | collapsed |
| # | SMA, % | Solvent, % | 1, % | 2, % | sec | 200:1 DHF | deg | AR | Type | C. | sec | % |
| FE-1 | TMDS | PGMEA | ACAC | AA | 270 | 9.9 | 91 | 26 | vapor | 115 | 180 | 98 |
| | 10 | 80 | 5 | 5 | | | | | | | | |
| FE-2 | TMDS | PGMEA | ACAC | | 280 | 10.1 | 94 | 27 | vapor | 105 | 180 | 88 |
| | 10 | 80 | 10 | | | | | | | | | |
| FE-3 | TMDS | PGMEA | ACAC | | 290 | 9.4 | 98 | 26 | vapor | 105 | 180 | 87 |
| | 10 | 85 | 5 | | | | | | | | | |
| FE-4 | TMDS | DMC | ACAC | | 290 | 9.5 | 97 | 27 | vapor | 90 | 180 | 79 |
| | 10 | 80 | 10 | | | | | | | | | |
| FE-5 | TMDS | DMC | | | 300 | 9.7 | 90 | 20 | vapor | 60 | 120 | 77 |
| | 6 | 94 | | | | | | | | | | |
| FE-6 | TMSDMA | PGMEA | ACAC | | 280 | 10.1 | 81 | 24 | vapor | 105 | 180 | 85 |
| | 17.6 | 72.4 | 10 | | | | | | | | | |
| FE-7 | TMDS | DMC | ACAC | | 290 | 9.7 | 101 | 23 | vapor | 90 | 180 | 94.4 |
| | 10 | 85 | 5 | | | | | | | | | |
| FE-8 | TMSDMA | DMC | | | 300 | 10.4 | 91 | 22 | vapor | 70 | 120 | 64 |
| | 17.6 | 82.4 | | | | | | | | | | |
| CE-1 | TMDS | DMC | | | 300 | 9.8 | 90 | 20 | liquid | 21 | 120 | 30 |
| | 6 | 94 | | | | | | | | | | |
| CE-2 | TMSDMA | DMC | | | 285 | 10.3 | 92 | 26 | liquid | 21 | 180 | 17 |
| | 17.6 | 82.4 | | | | | | | | | | |

FE = formulation example;
CE = comparative example;
SMA = surface modification agent;
DHF = Dilute HF typically 200:1;
CA = contact angle;
AR = aspect ratio;
SMT = surface modification technology;
TMDS = 1,1,3,3-tetramethyldisilazane;
TMSDA = trimethylsilyl-dimethylamine;
PGMEA = propylene glycol methyl ether acetate;
DMC = dimethyl carbonate;
ACAC = acetylacetone;
AA = acetic anhydride;
ThOx = thermal oxide

While the invention has been described in detail with reference to certain embodiments thereof, it will be understood that modifications and variations are within the spirit and scope of that which is described and claimed.

1. A surface treatment composition comprising:
at least one silylating agent;
at least one ketone;
at least one organic anhydride; and
at least one solvent.

2. The composition of claim 1, wherein the silylating agent is a disilazane.

3. The composition of claim 2, wherein the disilazane is 1,1,3,3-tetramethyldisilazane, hexamethyldisilazane, heptamethyldisilazane, N-methyl hexamethyldisilazane, 1,3-diphenyltetramethyldisilazane, or 1,1,3,3-tetraphenyl-1,3-dimethyldisilazane.

4. The composition of claim 1, wherein the silylating agent comprises a trimethylsilyl group.

5. The composition of claim 4, wherein the silylating agent is N-(trimethylsilyl) dimethylamine, N-(trimethylsilyl) diethylamine, 4-trimethylsilyloxy-3-penten-2-one, bis-trimethylsilylsulfate, methoxytrimethylsilane, N-allyl-N,N-bis(trimethylsilyl)amine, N,N-bis-trimethylsilyl urea, or tris-trimethylsilylphosphite.

6. The composition of claim 1, wherein the silylating agent is an aminosilane.

7. The composition of claim 6, wherein the aminosilane is bis(dimethylamino)dimethylsilane or phenethyldimethyl(dimethylamino) silane.

8. The composition of claim 1, wherein the silylating agent comprises from about 5 wt % to about 20 wt % of the composition.

9. (canceled)

10. The composition of claim 19, wherein the ketone is a diketone.

11. The composition of claim 10, wherein the ketone is acetylacetone.

12. The composition of claim 19, wherein the ketone is a monoketone.

13. The composition of claim 12, wherein the ketone is acetone, methyl ethyl ketone, methyl propyl ketone, methyl butyl ketone, methyl pentyl ketone, methyl hexyl ketone, methyl heptyl ketone, methyl octyl ketone, methyl amyl ketone, cyclohexanone, or cyclopentanone.

14. The composition of claim 1, wherein the ketone comprises from about 2 wt % to about 15 wt % of the composition.

15. The composition of claim 1, wherein the organic anhydride is selected from formic anhydride, acetic anhydride, propionic anhydride, or butyric anhydride.

16. The composition of claim 1, wherein the organic anhydride comprises from about 2 wt % to about 20 wt % of the composition.

17. The composition of claim 1, wherein the at least one solvent is selected from the group consisting of carbonate solvents, lactones, ketones, aromatic hydrocarbons, siloxanes, alkyl ethers, glycol dialkyl ethers, glycol alkyl ether acetates, esters, ureas, lactams, dimethyl sulfoxide, and N-methyl pyrrolidone.

18. (canceled)

19. The composition of claim 1, wherein the solvent comprises from about 70 wt % to about 95 wt % of the composition.

20. A method for treating a semiconductor substrate having a pattern disposed on a surface of the substrate, comprising:
contacting the surface of the substrate with a surface treatment composition, wherein the composition is dispersed onto the surface of the substrate in the vapor phase, wherein the composition comprises at least one silylating agent, at least one solvent, and at least one catalyst,
wherein the surface treatment composition forms a surface treatment layer on the surface such that the surface has a water contact angle of at least about 50 degrees; and
wherein the pattern comprises a feature having a dimension of at most about 20 nm.

21. A method for treating a semiconductor substrate having a pattern disposed on a surface of the substrate, comprising:
contacting the surface of the substrate with a surface treatment composition, wherein the composition is dispersed onto the surface of the substrate in the vapor phase, wherein the composition comprises:
at least one silylating agent;
at least one ketone;
at least one organic anhydride; and
at least one solvent.

22.-24. (canceled)

25. An article, comprising:
a semiconductor substrate; and
the surface treatment composition of claim 1 supported by the semiconductor substrate.

26.-30. (canceled)
